(19) United States
(12) Patent Application Publication
(10) Pub. No.: US 2023/0323543 A1
(43) Pub. Date: Oct. 12, 2023

(54) INTEGRATED CLEANING AND SELECTIVE MOLYBDENUM DEPOSITION PROCESSES

(71) Applicant: Applied Materials, Inc., Santa Clara, CA (US)

(72) Inventors: Tuerxun Ailihumaer, Santa Clara, CA (US); Yixiong Yang, Fremont, CA (US); Annamalai Lakshmanan, Fremont, CA (US); Srinivas Gandikota, Santa Clara, CA (US); Yogesh Sharma, Sunnyvale, CA (US); Pei Hsuan Lin, Millbrae, CA (US); Yi Xu, San Jose, CA (US); Zhimin Qi, Fremont, CA (US); Aixi Zhang, Santa Clara, CA (US); Shiyu Yue, Sunnyvale, CA (US); Yu Lei, Belmont, CA (US)

(73) Assignee: Applied Materials, Inc., Santa Clara, CA (US)

(21) Appl. No.: 17/714,513

(22) Filed: Apr. 6, 2022

(51) Int. Cl. C23C 30/00; C23C 16/02; C23C 16/455; C23C 16/56

(52) U.S. Cl. CPC C23C 30/00; C23C 16/0245; C23C 16/45525; C23C 16/56

(57) ABSTRACT

Embodiments of the disclosure advantageously provide in situ selectively deposited molybdenum films having reduced resistivity and methods of reducing or eliminating lateral growth of a selectively deposited molybdenum layer. Additional embodiments provide integrated clean and deposition processes which improve the selectivity of in situ selectively deposited molybdenum films on features, such as a via. Further embodiments advantageously provide methods of improving uniformity and selectivity of bottom-up gap fill for vias with improved film properties.

### TECHNICAL FIELD

Embodiments of the present disclosure pertain to methods for selective deposition of molybdenum within features. More particularly, embodiments of the disclosure are directed to methods which integrate cleaning and deposition processes for improved film properties.

### BACKGROUND

Interconnect metallization is widely used in logic and memory devices. A liner film followed by a bulk-deposited CVD/PVD film is typically used for via/trench gap fill applications. However, as the feature size decreases, the via/trench structures become smaller and the volume ratio of liner film increases, making it difficult to achieve defect free and low resistivity metal gap fill.

A selective deposition process takes advantage of an incubation difference on one surface material versus another surface material during deposition. This incubation delay could be leveraged to enable bottom-up gap fill without seam/void and liner films. There are several challenges, however, that prevent this technique from broader application. For example, impurities on the via bottom and dielectric surface can reduce selectivity of a selective metal growth on metal surface versus dielectric field. Current processes employing different direct plasma treatment (e.g., H₂ plasma and O₂ plasma) to clean surface contaminants (e.g., oxygen, carbon, fluorine, chlorine) can often experience the tradeoff between clean efficiency and selectivity: when the impurities and metal oxides are fully removed, the damaged caused by plasma would degrade the selectivity during following deposition.

In general, cleaning the metal surface efficiently while still maintaining no or minimal growth on the field is a major challenge preventing widespread use. Also, different surface structures with different etch residues or contaminants may need different pre-clean processes to enable selective growth.

Accordingly, there is a need for improved methods for integrated cleaning and selective molybdenum deposition within vias having improved film properties.

### SUMMARY

One or more embodiments of the disclosure are directed to a deposition method comprising exposing a top surface of a substrate comprising at least one feature to a plurality of chemical exposures. The at least one feature comprises at least one surface defining a via, the via comprising a bottom surface comprising a metal material and two sidewalls comprising a dielectric. The plurality of chemical exposures is configured to clean the bottom surface and the two sidewalls. The deposition comprises in situ selectively depositing a molybdenum film on the cleaned bottom surface.

Additional embodiments of the disclosure are directed to a deposition method comprising recessing a line of a metal material to form at least one feature on a top surface of a substrate. The at least one feature comprises at least one surface defining a via having a bottom surface and two sidewalls. The via has a depth to the bottom surface comprising a recessed metal material and a width between the two sidewalls comprising a dielectric. The deposition method comprises exposing the via to a plurality of chemical exposures to clean the bottom surface and the two sidewalls; and in situ selectively depositing a molybdenum film on the cleaned bottom surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a deposition method according to one or more embodiments;

FIG. 2A illustrates a cross-sectional view of a substrate according to one or more embodiments;

FIG. 2B illustrates a cross-sectional view of a substrate according to one or more embodiments;

FIG. 2C illustrates a cross-sectional view of a substrate according to one or more embodiments; and

FIG. 2D illustrates a cross-sectional view of a substrate according to one or more embodiments; and

FIG. 3 illustrates a schematic top-view diagram of a multi-chamber processing system according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used herein, the term “substrate surface” refers to any substrate surface upon which a layer may be formed. The substrate surface may have one or more features formed therein, one or more layers formed thereon, and combinations thereof. The shape of the feature can be any suitable shape including, but not limited to, peaks, trenches, and cylindrical vias. As used in this regard, the term “feature” refers to any intentional surface irregularity. Suitable examples of features include but are not limited to trenches which have a top, two sidewalls and a bottom, peaks which have a top and two sidewalls extending upward from a surface, and vias which have sidewalls extending down from a surface with an open bottom.

As used in this specification and the appended claims, the term “selectively” refers to process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface relative to the other surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Embodiments of the disclosure advantageously provide methods which reduce or eliminate lateral growth of a selectively deposited molybdenum layer. Additional embodiments provide an integrated clean and deposition which improves the selectivity of in situ selectively deposited molybdenum in a via. Further embodiments advantageously provide methods of improving uniformity and selectivity of bottom-up gap fill for vias with improved film properties.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

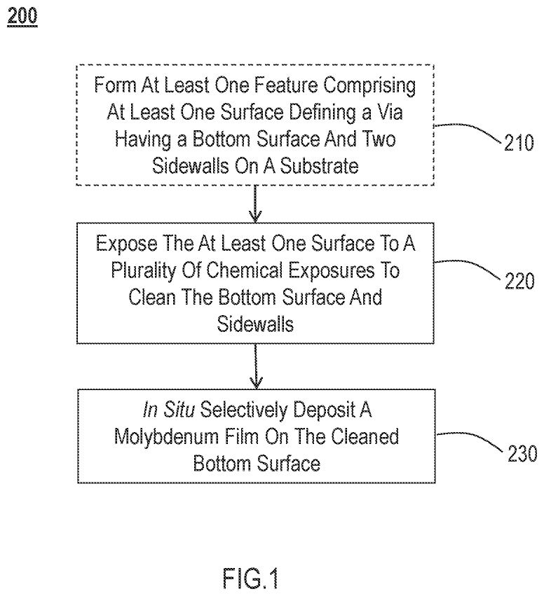

FIG. 1 depicts a process flow diagram of a deposition method 200 in accordance with one or more embodiments of the present disclosure. The deposition method 200, at operation 210, optionally includes forming at least one feature on a top surface of a substrate. The at least one surface comprises at least one surface defining a via having a bottom surface and two sidewalls. In some embodiments, operation 210 comprises recessing a line of a metal material to form the at least one feature comprising the at least one surface defining the via on the top surface of the substrate. At operation 220, the deposition method 200 comprises exposing the at least one surface to a plurality of chemical exposures to clean the bottom surface and the two sidewalls. At operation 230, the deposition method 200 comprises in situ selectively depositing a molybdenum film on the cleaned bottom surface.

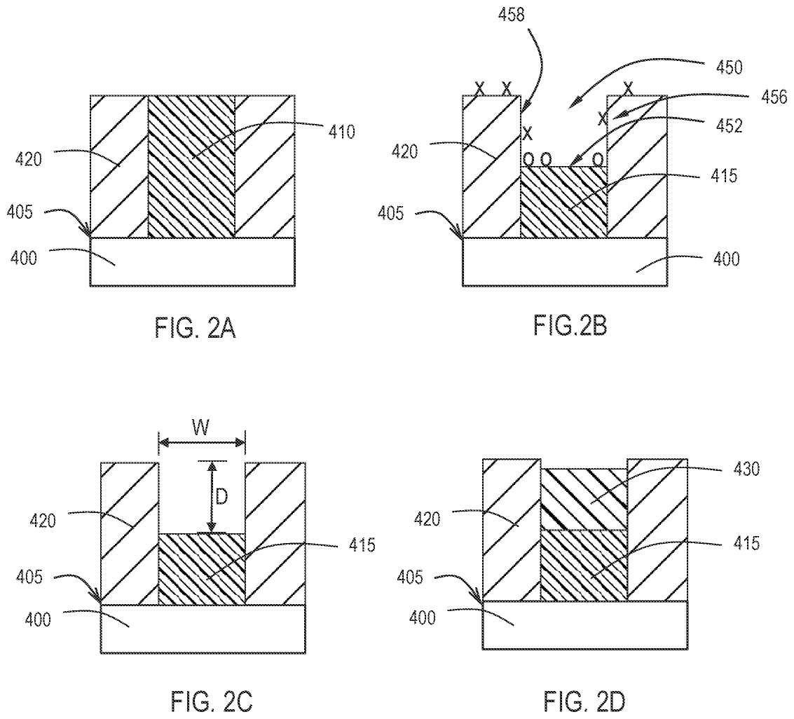

FIGS. 2A-2D illustrate cross-sectional views of a substrate 400 according to one or more embodiments. In some embodiments, FIGS. 2A-2D illustrate a substrate 400 that has been processed by the deposition method 200 illustrated in FIG. 1. FIG. 2A illustrates optional operation 210 of deposition method 200, which includes recessing a line of a metal material 140 to form a recessed metal material 415 and at least one feature on a top surface 405 of a substrate 400, the at least one feature comprising at least one surface defining a via 450 having a bottom surface 452 and two sidewalls 456, 458.

Referring to 2A-2D, the substrate 400 can be any suitable substrate material. In one or more embodiments, the substrate 400 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the substrate 400 comprises one or more of silicon (Si), germanium (Ge), gallium (Ga), arsenic (As), indium (In), phosphorus (P), or selenium (Se). Although a few examples of materials from which the substrate 400 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

Referring to FIG. 2A, the substrate 400 comprises at least one line of a metal material 410 bounded by a dielectric 420. In some embodiments, the deposition method 200, at operation 210, optionally includes recessing the metal material 410 to form the recessed metal material 415 and the at least one feature on the substrate 400, the at least one feature comprising at least one surface defining a via 450 having a bottom surface 452 comprising a recessed metal material 415 and two sidewalls 456, 458 comprising the dielectric 420. In some embodiments, the metal material 410 is recessed by a wet etch process to form the recessed metal material 415. In some embodiments, the metal material 410 is recessed by a dry etch process to form the recessed metal material 415.

The metal material 410 may be recessed any suitable depth to form the recessed metal material 415. In one or more embodiments, the metal material 410 is recessed a depth in a range of from 2 nm to 200 nm from the top surface of the dielectric 420. Thus, in one or more embodiments, the via 450 has a depth in a range of from 2 nm to 200 nm.

In one or more embodiments, the metal material 410 may be recessed by any suitable method known to the skilled artisan. In one or more embodiments, the metal material 410 may be recessed by one or more of wet etching and dry etching. In some embodiments, the dry etch process may include a conventional plasma etch, or a remote plasma-assisted dry etch process, such as a SiCoNi™ etch process, available from Applied Materials, Inc., located in Santa Clara, Calif. In a SiCoNi™ etch process, the device is exposed to H₂, NF₃, and/or NH₃ plasma species, e.g., plasma-excited hydrogen and fluorine species. For example, in some embodiments, the device may undergo simultaneous exposure to H₂, NF₃, and NH₃ plasma. The SiCoNi™ etch process may be performed in a SiCoNi™ Preclean chamber, which may be integrated into one of a variety of multi-processing platforms, including the Centura®, Dual ACP, Producer® GT, and Endura® platform, available from Applied Materials®. The wet etch process may include a hydrofluoric (HF) acid last process, i.e., the so-called “HF last” process, in which HF etching of surface is performed that leaves surface hydrogen-terminated. Alternatively, any other liquid-based pre-epitaxial pre-clean process may be employed. In some embodiments, the process comprises a sublimation etch for native oxide removal. The etch process can be plasma or thermally based. The plasma processes can be any suitable plasma (e.g., conductively coupled plasma, inductively coupled plasma, microwave plasma).

In one or more embodiments, the metal material 410 may comprise any suitable metal. In some embodiments, the metal material 410 includes one or more of copper (Cu), cobalt (Co), tungsten (W), molybdenum (Mo), and ruthenium (Ru). In some embodiments, the metal material 410 consists essentially of cobalt. In some embodiments, the metal material 410 consists essentially of tungsten. In some embodiments, the metal material 410 consists essentially of ruthenium. In some embodiments, the metal material 410 consists essentially of molybdenum. As used in this regard, a metal material which “consists essentially of” a stated element comprises greater than or equal to 95%, greater than or equal to 98%, greater than or equal to 99% or greater than or equal to 99.5% of the stated element on an atomic basis. Referring to FIGS. 2B-2D, in some embodiments, the recessed metal material 415 formed from the metal material 410 in FIG. 2A comprises the same material and has the same properties as the metal material 410.

Referring again to FIGS. 2A-2D, the dielectric 420 may comprise any suitable dielectric material known to the skilled artisan. As used herein, the term “dielectric material” refers to an electrical insulator that can be polarized in an electric field. In some embodiments, the dielectric material comprises one or more of oxides, carbon doped oxides, silicon dioxide (SiO₂), porous silicon dioxide (SiO₂), silicon nitride (SiN), silicon dioxide/silicon nitride, carbides, oxycarbides, nitrides, oxynitrides, oxycarbonitrides, polymers, phosphosilicate glass, fluorosilicate (SiOF) glass, or organosilicate glass (SiOCH). In one or more embodiments, the dielectric 420 is selected from silicon oxide (SiOₓ), silicon nitride (SiN), or combinations thereof. In some embodiments, the dielectric 420 consists essentially of silicon oxide. It is noted that the foregoing descriptors (e.g., silicon oxide) should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

The Figures show substrates having a single feature 450 for illustrative purposes; however, those skilled in the art will understand that there can be more than one feature 450. The shape of the feature 450 can be any suitable shape including, but not limited to, trenches and cylindrical vias. As used in this regard, the term “feature” means any intentional surface irregularity. Suitable examples of features include, but are not limited to, trenches and vias which have a top, two sidewalls and a bottom, and peaks which have a top and two sidewalls. In one or more embodiments, the at least one feature 450 comprises one or more of a trench or a via. In specific embodiments, the at least one feature 450 comprises a via. In still further embodiments, the term “at least one feature 450” and “via 450” may be used interchangeably. The via 450 has a depth D to the bottom surface 452 and a width W between the two sidewalls 456, 458. In some embodiments, the depth D is in a range of 2 nm to 200 nm, 3 nm to 200 nm, 5 nm to 100 nm, 2 nm to 100 nm, or 50 nm to 100 nm. In some embodiments, the width W is in a range of 10 nm to 100 nm, 10 nm to 20 nm, 10 nm to 50 nm, or 50 nm to 100 nm. In some embodiments, the via 450 has an aspect ratio (D/W) in a range of 1:1 to 20:1, 5:1 to 20:1, 10:1 to 20:1, or 15:1 to 20:1.

In one or more embodiments, the surfaces of the recessed metal material 415 (e.g., the bottom surface 452) and the dielectric 420 (e.g., the two sidewalls 456, 458) comprise contaminants, shown as O and X, respectively, in FIG. 2B. In some embodiments, the contaminants may include, but are not limited to, one or more of organic compounds, polymeric compounds, metal oxides, or metal nitrides. In some embodiments, the contaminants are created on the surfaces of the recessed metal material 415 (e.g., the bottom surface 452) and the dielectric 420 (e.g., the two sidewalls 456, 458) by the process which recesses the metal material 410 (e.g., the wet etch process or dry etch process) to form the recessed metal material 415.

At operation 220, the deposition method 200 comprises exposing a top surface 405 of a substrate 400 comprising at least one feature 450 to a plurality of chemical exposures to clean the surfaces of the recessed metal material 415 (e.g., the bottom surface 452) and the dielectric 420 (e.g., the two sidewalls 456, 458). In some embodiments, the temperature of the substrate 400 is controlled during the plurality of chemical exposures. In some embodiments, one or more of the plurality of chemical exposures is performed at a temperature in a range of 20° C. to 600° C., including in a range of from 20° C. to 550° C., in a range of from 20° C. to 500° C., in a range of from 20° C. to 450° C., in a range of from 20° C. to 400° C., in a range of from 20° C. to 350° C., in a range of from 20° C. to 300° C., in a range of from 20° C. to 250° C., in a range of from 20° C. to 200° C., in a range of from 20° C. to 150° C., in a range of from 20° C. to 100° C., in a range of from 100° C. to 500° C., or in a range of from 300° C. to 550° C.

In some embodiments, the processes of deposition method 200 are each performed within the same processing chamber. In some embodiments, the processes of deposition method 200 are each performed within a different processing chamber. In some embodiments, the different processing chambers are connected as part of a processing system. In some embodiments, the processes of deposition method 200 are performed without an intervening vacuum break.

In some embodiments, one or more of the plurality of chemical exposures is performed in situ without breaking vacuum. In some embodiments, one or more of the plurality of chemical exposures is performed ex situ. As used herein, the term “in situ” refers to processes of deposition method 200 that are each performed in the same processing chamber or a different processing chamber that is connected as part of a processing system, such that each of the processes of deposition method 200 are performed without an intervening vacuum break. As used herein, the term “ex situ” refers to processes of deposition method 200 that are each performed in the same processing chamber or a different processing chamber such that one or more of the processes of deposition method 200 are performed with an intervening vacuum break.

In some embodiments, the plurality of chemical exposures comprises one or more of a pump and purge process to remove moisture from the via 450, a plasma exposure, and a thermal soak. The plurality of chemical exposures may be performed any number of times and in any suitable order. The plurality of chemical exposures may be performed individually or together in any suitable combination.

In some embodiments, the plurality of chemical exposures comprises an ex situ combined pump and purge process and thermal soak, followed by an in situ combined pump and purge process and plasma exposure. In some embodiments, the plurality of chemical exposures comprises an in situ combined pump and purge process and thermal soak, followed by an in situ plasma exposure. In some embodiments, the plurality of chemical exposures comprises an in situ combined pump and purge process and plasma exposure.

In one or more embodiments, the pump and purge process may be performed at any suitable temperature and pressure. In some embodiments, the pump and purge process comprises maintaining the substrate 400 on a pedestal at a temperature in a range of from 300° C. to 500° C., a pressure in a range of from 10 Torr to 300 Torr, and an ampule (containing the precursor) temperature in a range of from 30° C. to 150° C.

In some embodiments, at least one of the plurality of chemical exposures comprises a plasma exposure. In some embodiments, the plasma exposure comprises one or more of a H₂ plasma exposure or a O₂ plasma exposure. In some embodiments the H₂ plasma exposure removes contaminants, shown as O and X, respectively, in FIG. 2B, from the surfaces of the recessed metal material 415 (e.g., the bottom surface 452) and the dielectric 420 (e.g., the two sidewalls 456, 458).

In one or more embodiments, the H₂ plasma exposure reduces the amount of or removes native metal oxide from the bottom surface 452 of the via 450. In some embodiments, the O₂ plasma exposure removes contaminants, shown as O and X, respectively, in FIG. 2A, from the surfaces of the recessed metal material 415 (e.g., the bottom surface 452) and the dielectric 420 (e.g., the two sidewalls 456, 458). In some embodiments, the O₂ plasma exposure increases selectivity of bottom-up gap fill.

In some embodiments, the plasma exposure comprises an inductively coupled plasma (ICP). In some embodiments, the plasma exposure comprises exposure to a directional inductively coupled plasma (ICP) with argon (Ar) sputtering. In some embodiments, the plasma is a capactively coupled plasma (CCP). In some embodiments, the plasma is generated remotely. In some embodiments, the plasma is generated within the processing chamber (direct plasma).

In some embodiments, the plasma exposure comprises an in situ plasma exposure directional inductively coupled plasma (ICP) with argon (Ar) sputtering. In one or more embodiments, the directional inductively coupled plasma (ICP) with argon (Ar) sputtering comprises sputtering a layer of argon (Ar) having a thickness in a range of from 5 Å to 40 Å. In some embodiments, the directional inductively coupled plasma (ICP) with argon (Ar) sputtering removes native metal oxide from the bottom surface 452 of the via 450. In some embodiments, the directional inductively coupled plasma (ICP) with argon (Ar) sputtering removes impurities from the two sidewalls 456, 458. In some embodiments, the directional inductively coupled plasma (ICP) with argon (Ar) sputtering removes contaminants, shown as O and X, respectively, in FIG. 2A, from the surfaces of the recessed metal material 415 (e.g., the bottom surface 452) and the dielectric 420 (e.g., the two sidewalls 456, 458).

In one or more embodiments, at least one of the plurality of chemical exposures comprises a thermal soak. A thermal soak will be understood by one skilled in the art to comprise exposing the via 450 to a chemical agent without the use of plasma or other radicals. In one or more embodiments, the thermal soak removes native metal oxide from the bottom surface 452 of the via 450. In some embodiments, the thermal soak comprises exposing the via 450 to one or more of tungsten hexafluoride (WF₆), tungsten hexachloride (WCl₆), tungsten (VI) oxytetrachloride (WOCl₄), tungsten pentachloride (WCl₅), molybdenum pentachloride (MoCl₅), molybdenum oxytetrachloride (MoOCl₄), molybdenum dichloride dioxide (MoO₂Cl₂), and molybdenum hexafluoride (MoF₆).

In some embodiments, the thermal soak is performed ex situ and comprises exposing the via 450 to WCl₅. In some embodiments, the thermal soak is performed in situ and comprises exposing the via 450 to WCl₅. In one or more embodiments, the thermal soak is performed in situ and comprises exposing the via to MoCl₅. In some embodiments, the thermal soak is performed ex situ and comprises exposing the via to MoCl₅. In some embodiments, the thermal soak is in situ and comprises exposing the via to MoO₂Cl₂. In some embodiments, the thermal soak is ex situ and comprises exposing the via to MoO₂Cl₂.

At operation 230, a molybdenum film 430 is in situ selectively deposited on the cleaned surface of the recessed metal material 415. In some embodiments, the molybdenum film 430 is laterally bounded by the two sidewalls 456, 458 of the at least one feature 450. As used in this regard, “laterally bounded” means that the deposited material does not extend beyond the point of intersection between the top surface and the two sidewalls 456, 458. In some embodiments, the molybdenum film 430 extends above the at least one feature 450. In some embodiments, as shown in FIG. 2C, the molybdenum film 430 is entirely within the via 450. As used in this regard, a material which is “entirely within” a via does not extend above the via 450 and is laterally bounded by the two sidewalls 456, 458 of the via 450. In some embodiments, the molybdenum film 430 fills the via 450. As used in this regard, a film which “fills the via” has a volume which occupies at least 95%, at least 98%, or at least 99% of the volume of the via 450. In some embodiments, the film which fills the via has a fill height in a range of from 30 nm to 75 nm, including in a range of from 40 nm to 60 nm.

Embodiments of the disclosure advantageously provide in situ selectively deposited molybdenum films 430 having reduced resistivity compared to molybdenum films deposited by processes other than those described herein (e.g., deposition method 200). Embodiments of the disclosure advantageously provide in situ selectively deposited molybdenum films 430 that are free or substantially free of voids and seams. As used in this regard, “substantially free” means that less than about 5%, including less than about 4%, less than about 3%, less than about 2%, less than about 1%, less than about 0.5%, and less than about 0.1% of the total composition of the in situ selectively deposited molybdenum film 430, on an atomic basis, comprises voids and/or seams.

Without intending to be bound by theory, it is thought that the plurality of chemical exposures improves the quality of the deposited molybdenum film 430. In some embodiments, the molybdenum film 430 deposited by the methods described herein demonstrate one or more of increased selectivity, decreased surface roughness, and/or decreased grain size.

In one or more embodiments, in situ selectively depositing the molybdenum film 430 comprises exposing the via 450 to a molybdenum precursor and a reductant. In some embodiments, the molybdenum precursor comprises one or more of MoCl₅, MoOCl₄, MoO₂Cl₂, or MoF₆. The reductant may be any suitable reducing agent known to the skilled artisan. In some embodiments, the reductant comprises H₂.

In one or more embodiments, in situ selectively depositing the molybdenum film 430 is performed at a temperature in a range of from 300° C. to 550° C. In some embodiments, selectively depositing the molybdenum film 430 is performed at a pressure in a range of from 10 Torr to 300 Torr.

The molybdenum film 430 may be in situ selectively deposited by any suitable process known to the skilled artisan. In one or more embodiments, selectively depositing the molybdenum film 430 comprises one or more of atomic layer deposition (ALD), co-flowing a molybdenum precursor and hydrogen (H₂), or chemical vapor deposition (CVD).

In one or more embodiments, the molybdenum film 430 is selectively deposited with a selectivity at least 20 times greater, at least 50 times greater, at least 100 times greater, at least 200 times greater, at least 500 times greater, at least 1,000 times greater, at least 2,000 times greater or at least 5,000 times greater than a similar process performed without the plurality of chemical exposures.

In some embodiments, the molybdenum film 430 has a roughness of less than or equal to 1 nm when the molybdenum film 430 has a thickness of 10 nm. In some embodiments, the molybdenum film 430 has a plurality of grains, each grain having a grain size of less than or equal to 15 nm, including less than or equal to 10 nm and less than or equal to 5 nm.

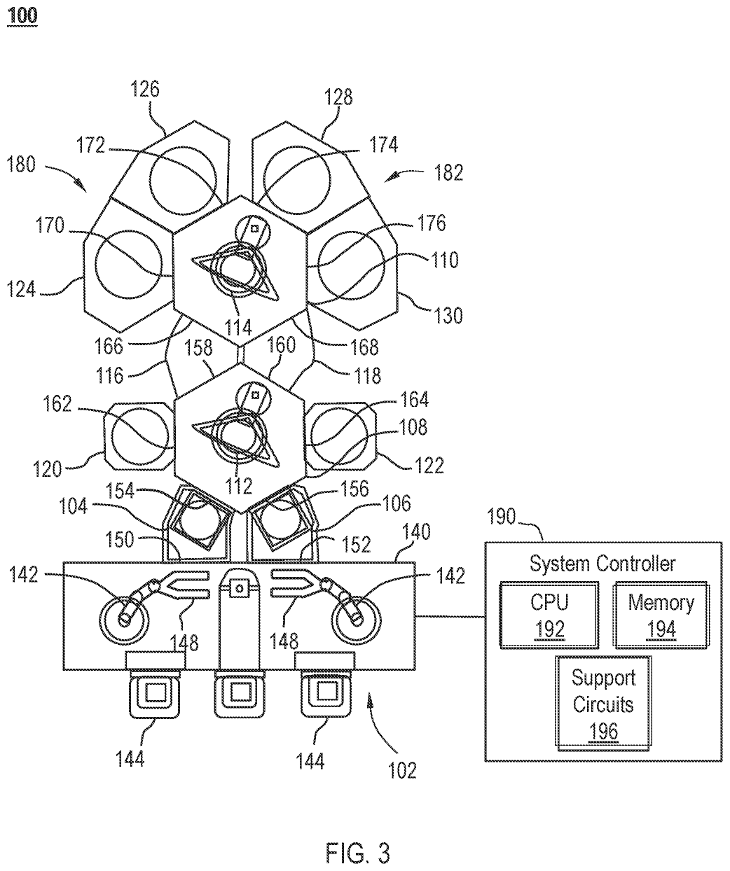

FIG. 3 is a schematic top-view diagram of an example of a multi-chamber processing system 100 according to embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide for an integrated solution for some processing of wafers.

Examples of a processing system that may be suitably modified in accordance with the teachings provided herein include the Endura®, Producer®, or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 3, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some embodiments, the processing chamber 120 can be capable of performing an annealing process, the processing chamber 122 can be capable of performing a cleaning process, and the processing chambers 124, 126, 128, 13o can be capable of performing epitaxial growth processes. In some examples, the processing chamber 122 can be capable of performing a cleaning process, the processing chamber 120 can be capable of performing an etch process, and the processing chambers 124, 126, 128, 130 can be capable of performing respective epitaxial growth processes. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random-access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

Processes may generally be stored in the memory of the system controller 190 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing chamber, causes the processing chamber to perform the operations of any of the methods (e.g., deposition method 200) described herein. In one or more embodiments, the controller causes the processing chamber to perform the operations of deposition method 200. In one or more embodiments, the controller causes the processing chamber to perform the operations of forming at least one feature on a top surface of a substrate (operation 210). The at least one feature comprises at least one surface defining a via having a bottom surface and two sidewalls (operation 210) by, e.g., recessing a line of a metal material to form the at least one feature comprising the at least one surface defining the via on the top surface of the substrate. In one or more embodiments, the controller causes the processing chamber to perform the operations of exposing the via to a plurality of chemical exposures to clean the bottom surface and two sidewalls (operation 220), and in situ selectively depositing a molybdenum film on the cleaned bottom surface (operation 230).

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A deposition method comprising:
exposing a top surface of a substrate comprising at least one feature to a plurality of chemical exposures, the at least one feature comprising at least one surface defining a via, the via comprising a bottom surface comprising a metal material and two sidewalls comprising a dielectric, the plurality of chemical exposure configured to clean the bottom surface and the two sidewalls; and
in situ selectively depositing a molybdenum film on the cleaned bottom surface.

2. The deposition method of claim 1, wherein the via has an aspect ratio in a range of 1:1 to 20:1.

3. The deposition method of claim 1, wherein the metal material comprises one or more of copper (Cu), cobalt (Co), tungsten (W), molybdenum (Mo), and ruthenium (Ru).

4. The deposition method of claim 1, wherein the dielectric comprises silicon oxide (SiOₓ), silicon nitride (SiN), or combinations thereof.

5. The deposition method of claim 1, wherein the plurality of chemical exposures comprises one or more of a pump and purge process to remove moisture from the via, a plasma exposure, and a thermal soak.

6. The deposition method of claim 1, wherein the plurality of chemical exposures comprises a plasma exposure.

7. The deposition method of claim 6, wherein the plasma exposure comprises one or more of a H₂ plasma exposure or a O₂ plasma exposure.

8. The deposition method of claim 5, wherein the thermal soak comprises exposing the via to one or more of tungsten hexafluoride (WF₆), tungsten hexachloride (WCl₆), tungsten (VI) oxytetrachloride (WOCl₄), tungsten pentachloride (WCl₆), molybdenum pentachloride (MoCl₅), molybdenum oxytetrachloride (MoOCl₄), molybdenum dichloride dioxide (MoO₂Cl₂), and molybdenum hexafluoride (MoF₆).

9. The deposition method of claim 5, wherein the plasma exposure comprises exposure to a directional inductively coupled plasma (ICP) with argon (Ar) sputtering.

10. The deposition method of claim 1, wherein the plurality of chemical exposures is performed at a temperature in a range of 20° C. to 600° C.

11. The deposition method of claim 1, wherein one or more of the plurality of chemical exposures is performed in situ without breaking vacuum.

12. The deposition method of claim 1, wherein one or more of the plurality of chemical exposures is performed ex situ.

13. The deposition method of claim 1, wherein the molybdenum film is deposited with a selectivity at least 1000 times greater than a similar process performed without the plurality of chemical exposures.

14. The deposition method of claim 1, wherein selectively depositing the molybdenum film comprises one or more of atomic layer deposition (ALD), co-flowing a molybdenum precursor and hydrogen (H₂), or chemical vapor deposition (CVD).

15. The deposition method of claim 1, wherein the molybdenum film has a roughness of less than or equal to 1 nm.

16. The deposition method of claim 1, wherein the molybdenum film has a plurality of grains, each grain having a grain size of less than or equal to 15 nm.

17. A deposition method comprising:
recessing a line of a metal material to form at least one feature on a top surface of a substrate, the at least one feature comprising at least one surface defining a via having a bottom surface and two sidewalls, the via having a depth to the bottom surface comprising a recessed metal material and a width between the two sidewalls comprising a dielectric;
exposing the via to a plurality of chemical exposures to clean the bottom surface and the two sidewalls; and
in situ selectively depositing a molybdenum film on the cleaned bottom surface.

18. The deposition method of claim 17, wherein the line of the metal material is recessed by a wet etch process or a dry etch process.

19. The deposition method of claim 17, wherein the molybdenum film is deposited entirely within the via.

20. The deposition method of claim 17, wherein the plurality of chemical exposures comprises one or more of a pump and purge process to remove moisture from the via, a plasma exposure, and a thermal soak.
